(19) United States
(12) Patent Application Publication
(10) Pub. No.: US 2023/0360911 A1
(43) Pub. Date: Nov. 9, 2023

(54) SEMICONDUCTOR MULTILAYER STRUCTURE AND MANUFACTURING METHOD THEREFOR, AND MANUFACTURING METHOD FOR SEMICONDUCTOR DEVICE

(71) Applicant: Nippon Telegraph and Telephone Corporation, Tokyo (JP)

(72) Inventors: Yuki Yoshiya, Tokyo (JP); Takuya Hoshi, Tokyo (JP); Hiroki Sugiyama, Tokyo (JP); Hideaki Matsuzaki, Tokyo (JP)

(21) Appl. No.: 18/247,013

(22) PCT Filed: Nov. 4, 2020
(86) PCT No.: PCT/JP2020/041169

§ 371 Date: Mar. 28, 2023

(51) Int. Cl. H01L 21/02; H01L 29/66; H01L 21/762

(52) U.S. Cl. CPC H01L 21/0254; H01L 29/66462; H01L 21/76254; H01L 21/02381

(57) ABSTRACT

After a nitride semiconductor layer is formed through crystal-growth of a nitride semiconductor containing Ga in a +c-axis direction on the other substrate, the other substrate on which the nitride semiconductor layer is formed is bonded to a substrate in a state where a surface on which the nitride semiconductor layer of the other substrate is formed is on the side of the substrate (a bonding step). This bonding is performed by bonding the surfaces to be bonded by a known direct bonding technology.

### CROSS-REFERENCE TO RELATED APPLICATIONS

This patent application is a national phase filing under section 371 of PCT application no. PCT/JP2020/041169, filed on Nov. 4, 2020, which application is incorporated herein by reference in its entirety.

### TECHNICAL FIELD

The present invention relates to a semiconductor laminate structure formed of a nitride semiconductor, a method of manufacturing the same, and a method of manufacturing a semiconductor device.

### BACKGROUND

A heterojunction field effect transistor (HFET) and a high electron mobility transistor (HEMT) are transistors that perform ON/OFF by changing a carrier density of a channel layer by an electric field generated by a gate voltage. When GaN is used, a 2-dimensional electron gas (2DEG) formed by collecting electrons at an interface to compensate for a difference in magnitude of polarization between AlGaN and GaN at the time of lamination of AlGaN/GaN is used in many cases. In a general HEMT using GaN of a Ga polarity (Group III polarity), a gate electrode is formed on an AlGaN layer of about several nm to several tens of nm, and a 2DEG concentration at an AlGaN/GaN interface is controlled.

In the HEMT using GaN, a high frequency device is applied utilizing the high mobility of 2DEG. Here, in the HEMT of Ga polarity, AlGaN with a large band gap is disposed on a device surface. Therefore, this type of transistor has a problem that, first, contact resistance is high and, second, an AlGaN layer cannot be thinned for maintaining carrier density, which leads to a short channel effect.

This problem hinders an improvement in high frequency characteristics of an HEMT in which a nitride semiconductor such as GaN is used. In order to solve the above-described problem, techniques of, firstly, in order to reduce the contact resistance, the region directly under an ohmic electrode being regrown, and secondly, in order to inhibit a short channel effect, increasing an Al composition and thinning an AlGaN layer have been examined. However, there is a limitation on a reduction in the ohmic contact resistance.

The GaN layer of which a main surface has N polarity (Group V polarity) is a crystal layer obtained by inverting the GaN layer of which the main surface has Ga polarity and has the following three advantages when the HEMT is formed. First, an AlGaN layer, which requires a high Al composition and a thickness of about 20 nm to supply carriers and has high resistance, is located below the GaN channel layer and is not disposed between an electrode and a channel. Therefore, the contact resistance can be reduced.

Second, since the thickness of the GaN layer on the surface does not have a great influence on the carrier density, it is possible to reduce the thickness and inhibit the short channel effect.

Third, the AlGaN layer immediately below the channel serves as a back barrier, and thus the short channel effect can be inhibited.

From the viewpoint of these advantages, by producing an HEMT using an N-polar GaN layer, an improvement in high frequency characteristics of the HEMT can be expected (see Non Patent Literature 1).

As described above, it could be understood that an improvement in the high frequency characteristics of the HEMT can be expected by using a nitride semiconductor layer of which a main surface has N polarity (an N-polar nitride semiconductor layer), but the N-polar nitride semiconductor layer has a problem in crystal-growth.

It is known that the N-polar nitride semiconductor layer has a problem such as lower surface flatness and higher dislocation density than in a Ga-polar nitride semiconductor layer (see Non Patent Literature 2). There is also an example in which the foregoing problems have been solved to some extent by performing crystal-growth on a substrate with a large off angle to produce a transistor. In this case, however, it is known that a sheet resistance varies depending on a relationship between a direction of an off angle and a direction of a current flowing through a channel (see Non Patent Literature 3). Thus, a limitation is imposed on production of a device.

In order to avoid such a problem of crystal-growth in an N-polar nitride semiconductor, a technology in which a nitride semiconductor grown with Ga polarity is inverted and bonded to another substrate to expose an N-polar surface to produce a device has been examined (Non Patent Literature 4). In this technology, since a Group III nitride semiconductor that has a device structure with Ga polarity is grown, it can be expected that qualities specific to crystals such as dislocation density and anisotropy of sheet resistance will be equivalent to those of existing Ga polarity transistors.

Further, by using substrate transfer, it is possible to produce an HEMT formed of a high-quality N-polar nitride semiconductor on a substrate on which it is difficult to grow an N-polar nitride semiconductor. For example, it is difficult to realize crystal-growth of GaN on a Si substrate that has a main surface plane orientation as (100), which is used for CMOS production, but it is possible to form an N-polar GaN layer on a Si substrate by using the above-described substrate transfer technology. Accordingly, an HEMT and a CMOS that have excellent high-frequency characteristics can be integrated on the same substrate.

### CITATION LIST

### Non Patent Literature

Non Patent Literature 1: M. H. Wong et al., “INVITED REVIEW N-polar GaN epitaxy and high electron mobility transistors”, Semiconductor Science and Technology, vol. 28, 074009, 2013.
Non Patent Literature 2: M. Sumiya et al., “Growth mode and surface morphology of a GaN film deposited along the N-face polar direction on c-plane sapphire substrate”, American Institute of Physics, vol. 88, no. 2, pp. 1158-1165, 2000.
Non Patent Literature 3: S. Keller et al., “Influence of the substrate misorientation on the properties of N-polar InGaN/GaN and AlGaN/GaN heterostructures”, Journal of Applied Physics, vol. 104, no. 9, 093510, 2008.
Non Patent Literature 4: J. W. Chung et al., “N-Face GaN/AlGaN HEMTs Fabricated Through Layer Transfer Technology”, IEEE Electron Device Letters, vol. 30, no. 2, pp. 113-116, 2009.
Non Patent Literature 5: K. K. Ryu et al., “Thin-Body N-Face GaN Transistor Fabricated by Direct Wafer Bonding”, IEEE Electron Device Letters, vol. 32, no. 7, pp. 895-897, 2011.

### SUMMARY

### Technical Problem

As described above, by forming an N-polar nitride layer on a Si substrate that has a plane orientation of the main surface as (100), production of a device in a CMOS process line in which a large-diameter Si substrate is used, integration with a CMOS circuit on the same substrate, and the like can be realized. For example, in a report, a resin or an oxide is used as an adhesive layer for bonding in substrate transfer. However, these adhesive layers cannot sufficiently draw out the characteristics of the device because of the characteristics of constituent materials.

For example, in Non Patent Literature 4, a Si substrate and a Group III nitride semiconductor epitaxial wafer are bonded by hydrogen silsesquioxane (HSQ). However, since HSQ only has heat resistance up to about 900° C., HSQ can withstand annealing of an ohmic electrode (about 850° C.), but a process exceeding 1000° C. cannot be performed after a bonding step. As a process in which a temperature exceeds 1000° C., for example, regrowth of GaN or etching in accordance with a selective thermal decomposition method can be considered. The regrowth of GaN is an important step of reducing contact resistance of a HEMT using an N-polar GaN layer, and a high temperature is necessary for high quality of the GaN crystal that is regrown. The selective thermal decomposition method is a method of etching GaN at high selectivity and is a step necessary for etching a thin film with good controllability.

In order to be able to carry out a high-temperature step, first, it is conceivable to perform direct bonding. In order to enable the high temperature process, second, a method of using an adhesive layer that can withstand higher temperatures is considered.

When direct bonding is used, inclusion of Ga in a nitride semiconductor layer in contact with a Si substrate may cause a problem at high temperatures. Ga and Si react at a high temperature, and GaN is etched by meltback etching. Accordingly, the nitride semiconductor layer containing Ga is likely to be peeled off from the Si substrate. When a device that includes the nitride semiconductor layer containing Ga is close to a substrate, it is conceivable that a layer in which the device is formed is etched and characteristics of the device considerably deteriorate.

On the other hand, there is a report that SiO₂ is used as an adhesive layer that can withstand higher temperatures (Non Patent Literature 5). However, since SiO₂ has a low thermal conductivity, heat dissipation of the device is greatly reduced, which is a limitation when high frequency characteristics of the HEMT need to be brought out.

As described above, the technology of the related art has a problem that a device that uses a nitride semiconductor containing Ga and has good characteristics cannot be formed on a Si layer of which a plane orientation of the main surface is (100).

Embodiments of the present invention have been made to solve the foregoing problems and an embodiment of the present invention is to enable to form a device that uses a nitride semiconductor containing Ga and has good characteristics on a Si layer having a plane orientation of a main surface as (100).

### Solution to Problem

A method of manufacturing a semiconductor laminate structure according to embodiments of the present invention includes: a bonding step of bonding a substrate that has a main surface formed as a (100) plane of Si and another substrate that has a nitride semiconductor layer formed through crystal-growth of a nitride semiconductor containing Ga to each other in a +c-axis direction, in a state where a surface of the other substrate on which the nitride semiconductor layer is formed is on a side of the substrate; an adhesive layer forming step of forming an adhesive layer formed of AlN, on at least one of a surface of the substrate on a side bonded to the other substrate and a surface of the nitride semiconductor layer on a side bonded to the substrate, before the bonding step; and a removing step of removing the other substrate from the nitride semiconductor layer after the bonding step.

A method of manufacturing a semiconductor device according to embodiments of the present invention includes: a bonding step of bonding a substrate that has a main surface formed as a (100) plane of Si and another substrate that has a nitride semiconductor layer formed through crystal-growth of a nitride semiconductor containing Ga to each other in a +c-axis direction, in a state where a surface of the other substrate on which the nitride semiconductor layer is formed is on a side of the substrate; an adhesive layer forming step of forming an adhesive layer formed of AlN, on at least one of a surface of the substrate on a side bonded to the other substrate and a surface of the nitride semiconductor layer on a side bonded to the substrate, before the bonding step; a removing step of removing the other substrate from the nitride semiconductor layer after the bonding step; a first element forming step of forming a recess on the surface of the nitride semiconductor layer after the removing step; a second element forming step of selectively regrowing n-type GaN in the recess to form an n-GaN layer; and a third element forming step of forming an electrode in ohmic contact with the n-GaN layer.

A method of manufacturing a semiconductor device according to embodiments of the present invention includes: a bonding step of bonding a substrate that has a main surface formed as a (100) plane of Si and another substrate that has a nitride semiconductor layer formed through crystal-growth of a nitride semiconductor containing Ga to each other in a +c-axis direction, in a state where a surface of the other substrate on which the nitride semiconductor layer is formed is on a side of the substrate; an adhesive layer forming step of forming an adhesive layer formed of AlN, on at least one of a surface of the substrate on a side bonded to the other substrate and a surface of the nitride semiconductor layer on a side bonded to the substrate, before the bonding step; a first element forming step of forming an element formation layer through crystal-growth of a nitride semiconductor containing Ga in the +c-axis direction on the other substrate, forming an etching stop layer through crystal-growth of a nitride semiconductor containing Al and having a higher thermal decomposition temperature than that of GaN in the +c-axis direction on the element formation layer, subsequently forming a buffer layer through crystal-growth of a nitride semiconductor containing Ga on the etching stop layer, and forming the nitride semiconductor layer including the element formation layer, the etching stop layer, and the buffer layer, before the adhesive layer forming step before the bonding step; a removing step of removing the other substrate from the nitride semiconductor layer after the bonding step; and a second element forming step of selectively thermally decomposing the buffer layer with respect to the etching stop layer by heating in a hydrogen atmosphere containing ammonia to remove the buffer layer and expose the etching stop layer, after the removing step.

A semiconductor laminate structure according to embodiments of the present invention includes a substrate that has a main surface formed as a (100) plane of Si, an adhesive layer formed of AlN and formed on the substrate, and a nitride semiconductor layer formed of a nitride semiconductor containing Ga and formed on the adhesive layer.

### Advantageous Effects of Embodiments of the Invention

As described above, according to embodiments of the present invention, since the substrate that has the main surface formed as the (boo) plane of Si and the other substrate on which the nitride semiconductor layer obtained through crystal-growth of the nitride semiconductor containing Ga in the +c-axis direction is formed are bonded together via the adhesive layer formed of AlN, it is possible to form a device having good characteristics using the nitride semiconductor containing Ga on the layer of Si having the plane orientation of the main surface as (100).

### BRIEF DESCRIPTION OF THE DRAWINGS

FIG. 1A is a cross-sectional view illustrating a state of a semiconductor laminate structure in an intermediate step to describe a method of manufacturing the semiconductor laminate structure according to a first embodiment of the present invention.

FIG. 1B is a cross-sectional view illustrating a state of the semiconductor laminate structure in an intermediate step to describe the method of manufacturing the semiconductor laminate structure according to the first embodiment of the present invention.

FIG. 1C is a cross-sectional view illustrating a state of the semiconductor laminate structure in an intermediate step to describe the method of manufacturing the semiconductor laminate structure according to the first embodiment of the present invention.

FIG. 1D is a cross-sectional view illustrating a state of the semiconductor laminate structure in an intermediate step to describe the method of manufacturing the semiconductor laminate structure according to the first embodiment of the present invention.

FIG. 1E is a cross-sectional view illustrating a state of the semiconductor laminate structure in an intermediate step to describe the method of manufacturing the semiconductor laminate structure according to the first embodiment of the present invention.

FIG. 1F is a cross-sectional view illustrating a state of the semiconductor laminate structure in an intermediate step to describe the method of manufacturing the semiconductor laminate structure according to the first embodiment of the present invention.

FIG. 2A is a cross-sectional view illustrating a state of the semiconductor device in an intermediate step to describe a method of manufacturing the semiconductor device according to a second embodiment of the present invention.

FIG. 2B is a cross-sectional view illustrating a state of the semiconductor device in an intermediate step to describe the method of manufacturing the semiconductor device according to the second embodiment of the present invention.

FIG. 2C is a cross-sectional view illustrating a state of the semiconductor device in an intermediate step to describe the method of manufacturing the semiconductor device according to the second embodiment of the present invention.

FIG. 3A is a cross-sectional view illustrating a state of the semiconductor device in an intermediate step to describe a method of manufacturing the semiconductor device according to a third embodiment of the present invention.

FIG. 3B is a cross-sectional view illustrating a state of the semiconductor device in an intermediate step to describe the method of manufacturing the semiconductor device according to the third embodiment of the present invention.

FIG. 3C is a cross-sectional view illustrating a state of the semiconductor device in an intermediate step to describe the method of manufacturing the semiconductor device according to the third embodiment of the present invention.

FIG. 3D is a cross-sectional view illustrating a state of the semiconductor device in an intermediate step to describe the method of manufacturing the semiconductor device according to the third embodiment of the present invention.

### DETAILED DESCRIPTION OF ILLUSTRATIVE EMBODIMENTS

### First Embodiment

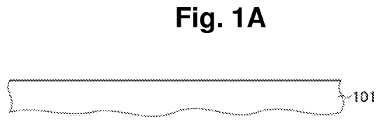

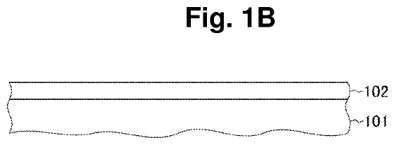

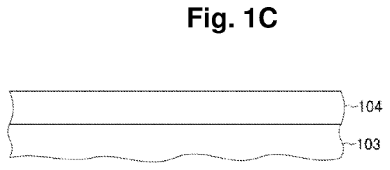

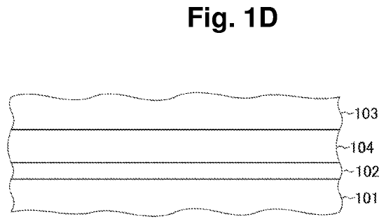

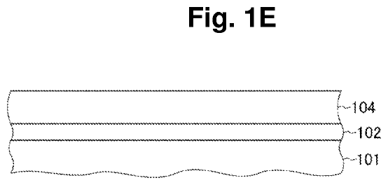

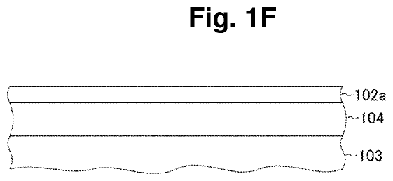

First, a method of manufacturing a semiconductor laminate structure according to a first embodiment of the present invention will be described with reference to FIGS. 1A to 1F.

First, as illustrated in FIG. 1A, a substrate 101 having a main surface formed as a (100) plane of Si is prepared. The substrate 101 can be, for example, a silicon on insulator (SOI) substrate that has a front surface silicon layer in which a plane orientation of the main surface is a (100) plane. The substrate 101 can be formed of bulk single crystal Si.

Next, as illustrated in FIG. 113, an adhesive layer 102 formed of AlN is formed on the substrate 101 (an adhesive layer forming step). The adhesive layer 102 can be formed by, for example, a well-known deposition technology such as sputtering. The adhesive layer 102 can be formed by a chemical vapor deposition (CVD) method in which electron cyclotron resonance (ECR) plasma is used. The adhesive layer 102 is a layer for preventing meltback etching by Si and Ga in a high temperature environment of 1000° C. or higher. The layer is better as the layer is thicker. However, if the layer is too thick, heat dissipation through the adhesive layer 102 deteriorates. Therefore, the layer thickness of the adhesive layer 102 is, for example, in the range of several nm to several hundreds of nm.

Next, as shown in FIG. 1C, a nitride semiconductor containing Ga is crystal-grown in a +c-axis direction on another substrate 103 to form a nitride semiconductor layer 104. At this stage, the main surface of the formed nitride semiconductor layer 104 serves as a +c plane and has Ga polarity (Group III polarity). The other substrate 103 may be a substrate on which a nitride semiconductor containing Ga such as GaN or AlGaN can be crystal-grown and can be, for example, any of a Si substrate, a sapphire substrate, a SiC substrate, and a GaN substrate. When the easiness of removal of the other substrate 103 from the nitride semiconductor layer 104 to be described below is taken into consideration, a Si substrate or a sapphire substrate is better. Here, for example, the other substrate 103 is assumed to be a sapphire substrate.

The nitride semiconductor layer 104 can be formed by epitaxially growing a target nitride semiconductor by, for example, metal organic chemical vapor deposition (MOCVD), molecular beam epitaxy (MBE), or the like. The nitride semiconductor layer 104 can have a laminate structure in which a plurality of nitride semiconductor layers is laminated. Each layer can be, for example, a layer for forming a transistor such as an HEMT. The outermost surface of the laminate structure can be, for example, a layer formed of GaN. It is preferable to form a material and a thickness of the outermost layer in consideration of chemical mechanical polishing (CMP) performed to secure surface flatness for bonding to be described below and occurrence of damage in the vicinity of a bonding interface due to pressurization in the bonding.

Next, as shown in FIG. 1D, the other substrate 103 on which the nitride semiconductor layer 104 is formed is bonded to the substrate 101 in a state where the surface on which the nitride semiconductor layer 104 of the other substrate 103 is formed is on the side of the substrate 101 (a bonding step). This bonding is performed by bonding the surfaces to be bonded by a known direct bonding technology. The direct bonding is required to have high flatness in which surface roughness Ra of each bonding surface is equal to or less than 1 nm. The outermost surface of the nitride semiconductor layer 104 immediately after the formation, as described above, may have insufficient flatness when direct bonding is formed with Ra of several nm. In this case, it is important to planarize the outermost surface of the nitride semiconductor layer 104 by CMP. In this way, by bonding the surfaces by a direct bonding technology, there is no need to use an adhesive formed of an organic substance or an oxide, resistance to high temperature processing is improved, and heat dissipation of a device is improved.

After the above-described bonding step, the other substrate 103 is removed from the nitride semiconductor layer 104 (a removing step). Then, as illustrated in FIG. 1E, the nitride semiconductor layer 104 is formed on the substrate 101 via the adhesive layer 102 and the surface of the nitride semiconductor layer 104 is exposed. For example, when the other substrate 103 is a sapphire substrate, the above-described removing can be performed by a laser lift-off method. For example, when the other substrate 103 is a Si substrate, the above-described removing can be performed by a back grinding method or dry etching. The main surface of the nitride semiconductor layer 104 at this stage is a surface facing the side of the other substrate 103, becomes a −c plane, and has N polarity (Group V polarity). When viewed from the substrate 101, the nitride semiconductor layer 104 is the same as a layer crystal-grown in the −c-axis direction.

As described with reference to FIG. 1C, after the nitride semiconductor layer 104 is formed on the other substrate 103, as illustrated in FIG. 1F, AlN is first crystal-grown on the nitride semiconductor layer 104 in the +c-axis direction to form an adhesive layer 102a formed of AlN. Next, by bonding the adhesive layer 102a on the other substrate 103 to the adhesive layer 102 on the substrate 101 illustrated in FIG. 1B, the substrate 101 and the other substrate 103 are bonded to each other, and then the other substrate 103 can be removed from the nitride semiconductor layer 104.

As described above, when the adhesive layer 102a is formed on the nitride semiconductor layer 104 through crystal-growth of AlN in the +c-axis direction, for example, the adhesive layer 102a can be grown on the lower nitride semiconductor layer 104 in the same growth furnace without being exposed to the atmosphere. However, in this case, AlN can grow only about several nm from the viewpoint of a critical film thickness. When epitaxial growth is performed so that the layer is thicker, the adhesive layer 102a is cracked, for example, which affects the nitride semiconductor layer 104 which is a lower layer on which the device is formed. Thus, it is preferable to use a growth method such as 3-dimensional growth at a low temperature for thick film growth of the adhesive layer 102a. Alternatively, the adhesive layer 102a formed of AlN can be formed by a sputtering method or the like.

Further, as described above, as illustrated in FIG. 1F, AlN is crystal-grown in the +c-axis direction on the nitride semiconductor layer 104 to form the adhesive layer 102a formed of AlN. Next, by bonding the adhesive layer 102a on the other substrate 103 to the main surface of the substrate 101 illustrated in FIG. 1A, the substrate 101 and the other substrate 103 are bonded to each other. Thereafter, the other substrate 103 can be removed from the nitride semiconductor layer 104.

As described with reference to FIG. 1B, after the adhesive layer 102 is formed on the substrate 101, a nitride semiconductor layer containing Ga is formed on the adhesive layer 102. Thereafter, bonding to the above-described substrate can be performed. When the adhesive layer 102 is formed, the layer of Si and the nitride semiconductor layer containing Ga do not come into contact with each other, and meltback etching is not performed.

The semiconductor laminate structure manufactured by the method of manufacturing the semiconductor laminate structure, as described above, includes the substrate 101 that has a main surface formed as a (boo) plane of Si, the adhesive layer 102 formed of AlN on the substrate, and the nitride semiconductor layer 104 formed of a nitride semiconductor containing Ga on the adhesive layer 102. The main surface of the nitride semiconductor layer 104 has N polarity. The nitride semiconductor layer 104 is bonded to the adhesive layer 102. Further, the adhesive layer 102 can be bonded to the substrate 101.

The semiconductor laminate structure obtained by the above-described method of manufacturing the semiconductor laminate structure can be a template substrate used for manufacturing a semiconductor device using a nitride semiconductor. The nitride semiconductor layer 104 can be used as a template substrate even in a state where the other substrate 103 is removed, but the nitride semiconductor layer 104 near the other substrate 103 is generally formed of a buffer layer including a nucleation layer or the like at the initial stage of crystal (epitaxial) growth, and has low crystal quality. The buffer layer is generally formed of GaN. Therefore, a device layer included in the nitride semiconductor layer 104 for forming the device structure is preferably grown by inserting the buffer layer that has a sufficient thickness.

Further, a layer of the nitride semiconductor layer 104 near the other substrate 103 is often removed together in the removing of the other substrate 103 in accordance with a method of peeling the other substrate 103. Therefore, the above-described buffer layer also has an effect of preventing the device layer from being removed together with the substrate. When the buffer layer is inserted, a desired layer is not exposed only by removing the other substrate 103. Therefore, a step of removing a portion serving as the buffer layer by a removing technology such as CMP or dry etching and exposing a desired layer (a device layer) to the surface is necessary. When the device layer is thin, etching with high selectivity is required, and an etch stop layer may be formed in advance along with the device layer. The buffer layer formed of GaN can be removed by a well-known selective thermal decomposition method.

The template that has the above-described semiconductor laminate structure can be used to manufacture an N-polar nitride semiconductor device on a Si substrate. The template with the semiconductor laminate structure can be used as a wafer for integrating the Si device and the N-polar nitride semiconductor device on the same substrate. For example, when an N-polar GaN device integrated with a CMOS circuit is manufactured using the above-described template, an N-polar GaN layer (the nitride semiconductor layer) in a region where the Si device is formed is first removed by etching to expose Si to the surface. A Si device can then be made in the exposed region. The nitride semiconductor layer can be removed by general dry etching. The nitride semiconductor layer of which a main surface has N polarity can also be removed by wet etching with KOH or the like, unlike a case where the main surface has Group III polarity. The CMOS process on the exposed Si substrate can be performed by using a known semiconductor device manufacturing technology.

### Second Embodiment

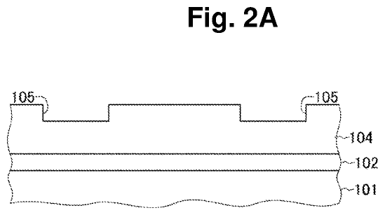

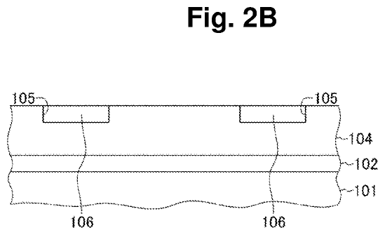

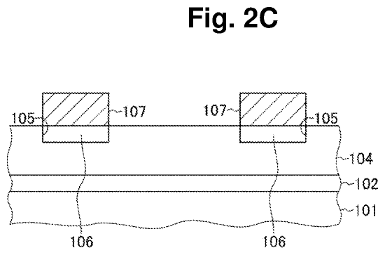

Next, a method of manufacturing a semiconductor device according to a second embodiment of the present invention will be described with reference to FIGS. 1A to 1F and FIGS. 2A to 2C. First, as described with reference to FIGS. 1A to 1F, the nitride semiconductor layer 104 is formed on the substrate 101 via the adhesive layer 102 so that the surface of the nitride semiconductor layer 104 is exposed.

Next (after the removing step), as shown in FIG. 2A, recesses 105 are formed on the surface of the nitride semiconductor layer 104 (a first element forming step). Here, two recesses 105 are formed. For example, the recess 105 can be formed by removing the nitride semiconductor layer 104 from the front surface side by a predetermined depth in accordance with a known etching technology (for example, dry etching) using a mask pattern formed by a known lithography technology.

Next, as illustrated in FIG. 2B, n-type GaN into which n-type impurities are introduced at high concentration is selectively regrown in the recess 105 to form an n⁺-GaN layer 106 (a second element forming step). Here, the n⁺-GaN layer 106 is formed in each of the two recesses 105.

Next, as illustrated in FIG. 2C, an electrode 107 in ohmic contact with the n⁺-GaN layer 106 is formed (a third element forming step). Here, the electrode 107 is formed on each of the two n⁺-GaN layers 106. For example, one of the two formed electrodes 107 can serve as, for example, a source electrode, and the other can serve as a drain electrode.

Thereafter, for example, a gate electrode for a Schottky junction is formed on the surface of the nitride semiconductor layer 104 between the two electrodes 107 and can serve as a field effect transistor.

For example, in the formation of the nitride semiconductor layer 104 described with reference to FIG. 1C, a device layer (an element formation layer) in which a GaN layer serving as a channel layer and an AlGaN layer serving as a barrier layer for generating 2DEG are grown in this order is formed in the nitride semiconductor layer 104. As described above, after the buffer layer is grown, the GaN layer and the AlGaN layer are grown. The nitride semiconductor layer 104 formed in this way is in a state in which a GaN layer to be a channel layer is formed on an AlGaN layer to be a barrier layer when viewed from the side of the substrate 101 on the substrate 101 after the other substrate 103 is removed. As the direction of the crystal axis of each layer, a direction in which each layer is formed when viewed from the substrate 101 side is a −c-axis direction.

In the nitride semiconductor layer 104 configured in this way, two electrodes 107 are formed, as described above. A gate electrode (not illustrated) is formed between the two electrodes 107 to serve as a field effect transistor having 2DEG generated in the barrier layer as a channel. As is well known, a nitride semiconductor has polarization in the c-axis direction. Therefore, by forming a heterojunction between the AlGaN layer and the GaN layer described above, a high-density 2DEG of about 10¹³ cm⁻³ can be spontaneously formed by the polarization effect.

Incidentally, the formation of the n⁺-GaN layer 106 is a general technology for reducing a contact resistance of the electrode 107, but the regrowth is performed at a high temperature equal to or greater than 1000° C., which is a general growth temperature of GaN. Therefore, when the above-described bonding is performed using an adhesive or the like that has no high heat resistance, the technology cannot be applied. On the other hand, the adhesive layer 102 has thermal resistance higher than 1000° C. and has thermal resistance higher than that of GaN. Therefore, even if the adhesive layer 102 is exposed to a high temperature in regrowth of GaN, problems such as deterioration in the adhesive layer 102 and occurrence of peeling in this portion do not occur. Since Si of the substrate 101 and Ga contained in the nitride semiconductor layer 104 are not in direct contact with each other, a reaction progresses at a bonding interface by meltback etching, and peeling or the like does not occur.

### Third Embodiment

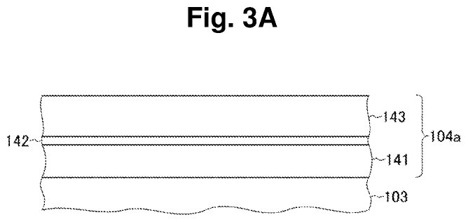

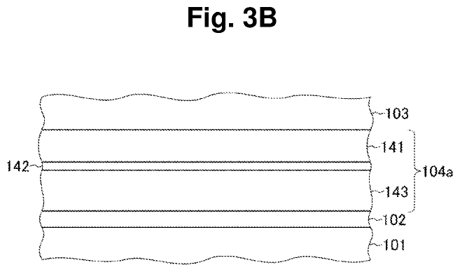

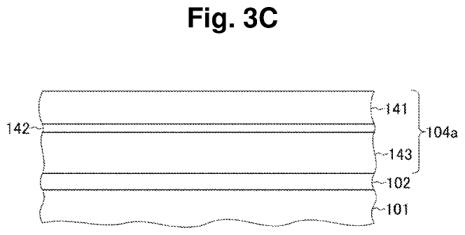

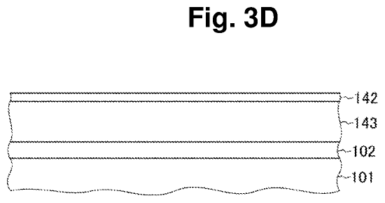

Next, a method of manufacturing a semiconductor device according to a third preferred embodiment of the present invention will be described with reference to FIGS. 1A to 1F and 3A to 3D. First, as described with reference to FIG. 1A, the substrate 101 is prepared. Subsequently, as described with reference to FIG. 1B, the adhesive layer 102 formed of AlN is formed on the substrate 101.

As described with reference to FIG. 1C, the nitride semiconductor layer 104 is formed through crystal-growth of a nitride semiconductor containing Ga on the other substrate 103 in the +c-axis direction.

Next, as shown in FIG. 3A, a nitride semiconductor containing Ga is crystal-grown in the +c-axis direction on the other substrate 103 to form a buffer layer 141. The buffer layer 141 can be formed with, for example, GaN. Subsequently, a nitride semiconductor containing Al and having a thermal decomposition temperature higher than GaN is crystal-grown in the +c-axis direction on the buffer layer 141 to form an etching stop layer 142. The etching stop layer 142 can be formed of AlGaN.

Subsequently, a nitride semiconductor containing Ga is crystal-grown in the +c-axis direction on the etching stop layer 142 to form an element formation layer 143. The element formation layer 143 can have, for example, a laminate structure of a GaN layer serving as a channel layer or the like, an AlGaN layer serving as a barrier layer or the like, and a GaN layer serving as a protective layer. At this stage, when viewed from the other substrate 103, a GaN layer serving as a channel layer, an AlGaN layer serving as a barrier layer, and a GaN layer serving as a protective layer are laminated in this order to form the element formation layer 143. A GaN layer serving as a protective layer is disposed on the uppermost layer of the element formation layer 143. The element formation layer 143 is a layer in which a basic structure of a device (a semiconductor device) such as a transistor is formed.

In this way, the nitride semiconductor layer 104a including the buffer layer 141, the etching stop layer 142, and the element formation layer 143 is formed (a first element forming step). The nitride semiconductor layer 104a is formed before the bonding step and before the adhesive layer forming step.

Next, as illustrated in FIG. 3B, the substrate 101 and the other substrate 103 on which the nitride semiconductor layer 104a is formed are bonded to each other in a state where the surface on which the nitride semiconductor layer 104 of the other substrate 103 is formed is on the side of the substrate 101 (a bonding step). The bonding is similar to the bonding described with reference to FIG. 1D. As described above, when the uppermost layer of the element formation layer 143 is a GaN layer serving as a protective layer, the GaN layer serving as a channel layer or the like, the AlGaN layer serving as a barrier layer or the like, or the like can be protected from pressure or the like applied in the above-described bonding.

Next, through a removing step of removing the other substrate 103 from the nitride semiconductor layer 104a to expose the buffer layer 141, as illustrated in FIG. 3C, the nitride semiconductor layer 104a is formed on the substrate 101 via the adhesive layer 102, and the surface of the nitride semiconductor layer 104a (the buffer layer 141) is exposed. The removing of the other substrate 103 is similar to the description using FIG. 1E. The main surface of the nitride semiconductor layer 104a (the buffer layer 141) at this stage is a surface facing the side of the other substrate 103, becomes a −c plane, and has N polarity (Group V polarity). When viewed from the substrate 101, the nitride semiconductor layer 104a (the element formation layer 143, the etching stop layer 142, and the buffer layer 141) is the same as the layer crystal-grown in the −c-axis direction.

Next, the buffer layer 141 is selectively thermally decomposed on the etching stop layer 142 by heating in a hydrogen atmosphere containing ammonia to remove the buffer layer 141, and the etching stop layer 142 is exposed, as illustrated in FIG. 3D (a second element forming step). Since AlGaN has a higher thermal decomposition temperature than GaN, etching can be performed by selectively thermally decomposing GaN by the above-described selective thermal decomposition method. The selectivity of the selective thermal decomposition method is as high as about 10³ depending on a condition, and is effective when a thin layer is exposed to the surface by etching.

The element formation layer 143 may have a total thickness of about several 10 nm, including an AlGaN layer serving as a barrier layer or the like and a GaN layer serving as a channel layer or the like. On the other hand, the buffer layer 141 disposed on the side of the other substrate 103 in the growth can have a thickness of several hundreds of nm to several lam in order to sufficiently reduce the dislocation density generated by a lattice matching difference with the other substrate 103. Therefore, high selectivity in etching is important between the etching stop layer 142 and the buffer layer 141.

Further, by performing the selective thermal decomposition method in a hydrogen atmosphere containing ammonia, it is possible to selectively control the etching rate of the buffer layer 141. When ammonia is not used, an etching rate (an etching speed) is too fast, and it is difficult to stop etching in the etching stop layer 142 formed of AlGaN even if this layer is used. By controlling the etching rate using ammonia, it is possible to easily control etching to stop the etching in the etching stop layer 142.

In an etching process by the above-described selective thermal decomposition method, a processing temperature is as high as about 1000° C. However, since the adhesive layer 102 formed of AlN is formed, the substrate 101 and the nitride semiconductor layer 104a (the buffer layer 141) do not come into contact with each other, meltback etching due to a reaction between Ga and Si is prevented, and a bonding interface can be prevented from being rough and further from being peeled off. Since AlN has a higher thermal decomposition temperature than GaN, the adhesive layer 102 is hardly decomposed even under the condition of thermally decomposing GaN.

By removing the buffer layer 141, as described above, the main surface of the etching stop layer 142 is a surface facing the side of the other substrate 103, becomes a −c plane, and becomes N polarity (Group V polarity). When viewed from the substrate 101, the element formation layer 143 and the etching stop layer 142 are the same as layers crystal-grown in the −c-axis direction. The element formation layer 143 has a structure in which, for example, a GaN layer serving as a protective layer, an AlGaN layer serving as a barrier layer or the like, and a GaN layer serving as a channel layer or the like are laminated in this order when viewed from the substrate 101. Each layer has a surface on the upper side when viewed from the substrate 101 that has N polarity.

Thereafter (after the second element forming step), by forming an electrode (not shown) and the like on the element formation layer 143, it is possible to obtain a semiconductor device such as a transistor (a third element forming step). For example, the etching stop layer 142 on the element formation layer 143 can be used as a gate insulating layer, and a gate electrode can be formed on the gate insulating layer. After the etching stop layer 142 is removed, a gate electrode for Schottky connection can be formed in the channel layer which is the uppermost layer of the element formation layer 143. A source electrode and a drain electrode that are ohmically connected to a channel formed of 2-dimensional electron gas and formed in the vicinity of a heterointerface between a channel layer and a barrier layer of the element formation layer 143 can be formed with a gate electrode interposed therebetween.

As described above, according to embodiments of the present invention, the substrate that has the main surface formed as the (100) plane of Si and the other substrate on which the nitride semiconductor layer obtained through crystal-growth of the nitride semiconductor containing Ga in the +c-axis direction is formed are bonded together via the adhesive layer formed of AlN, and thus a device that has good characteristics using the nitride semiconductor containing Ga can be formed on the layer of Si that has the plane orientation of the main surface as (100).

The present invention is not limited to the embodiments described above, and it is obvious that many modifications and combinations can be implemented by those skilled in the art within the technical idea of the present invention.

### REFERENCE SIGNS LIST

101 Substrate
102 Adhesive layer
102a Adhesive layer
103 Other substrate
104 Nitride semiconductor layer
104a Nitride semiconductor layer
105 Recess
106 n⁺-GaN layer
107 Electrode
141 Buffer layer
142 Etching stop layer
143 Element formation layer

1.-8. (canceled)

9. A method of manufacturing a semiconductor laminate structure, the method comprising:
providing a first substrate comprising a main surface formed as a (100) plane of Si;
forming a nitride semiconductor layer on a second substrate through crystal-growth of a nitride semiconductor containing Ga;
forming an adhesive layer comprising AlN on the main surface of the first substrate or on a surface of the nitride semiconductor layer;
bonding the first substrate and the second substrate to each other in a +c-axis direction in a state in which the nitride semiconductor layer faces the first substrate; and
after the bonding, removing the second substrate from the nitride semiconductor layer.

10. The method according to claim 9, wherein a main surface of the nitride semiconductor layer has N polarity.

11. The method according to claim 9, further comprising forming the adhesive layer on the main surface of the first substrate and on the surface of the nitride semiconductor layer.

12. A method of manufacturing a semiconductor device comprising the semiconductor laminate structure of claim 9, the method comprising:
after removing the second substrate and exposing a second surface of the nitride semiconductor layer, forming a recess on the second surface of the nitride semiconductor layer;
selectively regrowing n-type GaN in the recess to form an n-GaN layer; and
forming an electrode in ohmic contact with the n-GaN layer.

13. The method according to claim 12, wherein the second surface of the nitride semiconductor layer has N polarity.

14. A method of manufacturing a semiconductor device, the method comprising:
providing a first substrate comprising a main surface formed as a (100) plane of Si;
forming a nitride semiconductor layer on a second substrate, wherein forming the nitride semiconductor layer comprises:
forming a buffer layer on the second substrate through crystal-growth of a first nitride semiconductor containing Ga in a +c-axis direction;
forming an etching stop layer on the buffer layer through crystal-growth of a nitride semiconductor containing Al and having a thermal decomposition temperature higher than that of GaN in the +c-axis direction; and
forming an element formation layer on the etching stop layer through crystal-growth of a second nitride semiconductor in the +c-axis direction;
forming an adhesive layer comprising AlN on the main surface of the first substrate or on a surface of the nitride semiconductor layer;
bonding the first substrate and the nitride semiconductor layer to each other in the +c-axis direction using the adhesive layer;
after the bonding, removing the second substrate from the nitride semiconductor layer; and
after the removing, selectively thermally decomposing the buffer layer with respect to the etching stop layer by heating in a hydrogen atmosphere containing ammonia to remove the buffer layer and to expose the etching stop layer.

15. The method according to claim 14, further comprising
after thermally decomposing the buffer layer, forming an electrode on the element formation layer.

16. The method according to claim 14, wherein a main surface of the nitride semiconductor layer has N polarity.

17. The method according to claim 14, wherein the buffer layer comprises GaN and the etching stop layer comprises AlGaN.

18. A semiconductor laminate structure comprising:
a substrate having a main surface that is a (100) plane of Si;
an adhesive layer comprising AlN on the substrate; and
a nitride semiconductor layer comprising a nitride semiconductor containing Ga on the adhesive layer.

19. The semiconductor laminate structure according to claim 18, wherein a main surface of the nitride semiconductor layer has N polarity.

20. The semiconductor laminate structure according to claim 18, wherein the nitride semiconductor layer is bonded to the adhesive layer.

21. The semiconductor laminate structure according to claim 18, wherein the adhesive layer is bonded to the substrate.
